(19) United States
(12) Patent Application Publication
(10) Pub. No.: US 2026/0260844 A1
(43) Pub. Date: Sep. 3, 2026

(54) PARTICLE DETECTOR WITH REDUCED INTER-SYMBOL INTERFERENCE

(71) Applicant: ASML Netherlands B.V., Veldhoven (NL)

(72) Inventors: Jan BEX, Pelt (BE); Marcellinus Johannes Maria PELGROM, Helmond (NL); Harald Gert Helmut NEUBAUER, Erlangen (DE); Matthias OBERST, Nürnberg (DE); Bernd Michael VOLLMER, Dresden (DE); Hindrik Willem MOOK, The Hague (NL); Utku ULUDAG, Delft (NL)

(73) Assignee: ASML Netherlands B.V., Veldhoven (NL)

(21) Appl. No.: 18/877,850

(22) PCT Filed: Jul. 24, 2023
(86) PCT No.: PCT/EP2023/070487

§ 371 Date: Dec. 20, 2024

(30) Foreign Application Priority Data
Aug. 8, 2022 (EP) 22189243.3

(51) Int. Cl. H01J 37/244; H10F 39/00; H10F 39/18

(52) U.S. Cl. CPC H01J 37/244; H10F 39/1892; H10F 39/1895; H10F 39/809; H10F 39/811; H01J 2237/2441

(57) ABSTRACT

Systems and methods for fabricating a substrate of a charged-particle detector for use in a charged-particle beam apparatus are disclosed. The substrate may include a charge sensing element formed on a first surface of the substrate and configured to detect charged particles originating from a sample; and a plurality of transistors formed in a first region of a second surface of the substrate, the second surface being opposite the first surface, wherein a top surface of each transistor of the plurality of transistors is coplanar with a top surface of the first region and with the second surface of the substrate.

### CROSS-REFERENCE TO RELATED APPLICATIONS

This application claims priority of EP application 22189243.3 which was filed on Aug. 8, 2022 and which is incorporated herein in its entirety by reference.

### TECHNICAL FIELD

The description herein relates to particle detectors that may be useful in the field of charged-particle beam systems, and more particularly, to charged-particle detectors with reduced inter-symbol interference.

### BACKGROUND

Detectors may be used for sensing physically observable phenomena. For example, charged particle beam tools, such as electron microscopes, may comprise detectors that receive charged particles projected from a sample and that output detection signals. Detection signals may be used to reconstruct images of sample structures under inspection and may be used, for example, in metrology processes or to reveal defects in the sample. Metrology relates to precision measurements of sample structures and other miniaturized features. For example, in a semiconductor wafer, metrology may include such measurements as critical dimension (width of the smallest device feature), critical dimension uniformity, linewidth, overlay, line edge roughness, line end shortening, floor tilt, sidewall angle, and other dimensional parameters. Metrology may also include material analysis based on reconstructed images from the detection signals. Detection of defects in a sample is also increasingly important in the manufacturing of semiconductor devices, which may include large numbers of densely packed, miniaturized integrated circuit (IC) components. Inspection systems may be provided for these and other purposes.

Existing multi-beam inspection apparatuses typically use pixelated detectors for charged-particle detection. The pixelated detectors may include an array of diodes arranged on a layer for picking up charged particles and generating signals, as well as a corresponding array of transistors arranged on another layer for picking up the signals. To electrically isolate the diodes, shallow-trench isolation (“STI”) topology is typically used. A shallow trench may be created between two diodes by depositing a silicon-dioxide layer with thickness of typically hundreds of nanometers. However, when the detector having the STI topology is exposed to ion implantation, the silicon-dioxide layer may be difficult for the charge carriers to penetrate for subsequent implantations. Both may cause lower implantation doses under areas covered by the shallow trenches, and further cause charge buildup (referred to as “fixed charges” herein) near transistor channels of the detector. Such fixed charges may affect performance and functionality of the detector.

### SUMMARY

Embodiments of the present disclosure provide systems and methods for fabricating a substrate of a charged-particle detector for use in a charged-particle beam apparatus. The substrate may include a charge sensing element formed on a first surface of the substrate and configured to detect charged particles originating from a sample; and a plurality of transistors formed in a first region of a second surface of the substrate, the second surface being opposite the first surface, wherein a top surface of each transistor of the plurality of transistors is coplanar with a top surface of the first region and with the second surface of the substrate.

Another aspect of the present disclosure is directed to a charged-particle detector. The charged-particle detector may include a substrate layer comprising a first surface and a second surface opposite the first surface; a charge sensing element formed on the first surface and configured to detect charged particles originating from a sample; and a plurality of transistors formed in a first region of the second surface of the substrate, wherein a top surface of each transistor of the plurality of transistors is coplanar with a top surface of the first region and the second surface of the substrate.

Yet another aspect of the present disclosure is directed to a charged-particle beam apparatus. The apparatus may include a charged-particle source configured to emit primary charged particles to be incident on a sample; and a charged-particle detector configured to detect secondary charged particles generated from the sample upon interaction with the primary charged particles. The charged-particle detector may include a substrate layer comprising a first surface and a second surface opposite the first surface; a charge sensing element formed on the first surface and configured to detect charged particles originating from a sample; and a plurality of transistors formed in a first region of the second surface of the substrate, wherein a top surface of each transistor of the plurality of transistors is coplanar with a top surface of the first region and with the second surface of the substrate.

Yet another aspect of the present disclosure is directed to a method for fabricating a substrate of a charged-particle detector. The method may include the steps of forming a charge sensing element on a first surface of the substrate, the charge sensing element configured to detect charged particles originating from a sample; forming a plurality of transistors in a first region of a second surface of the substrate, the second surface being opposite the first surface, wherein a top surface of each transistor of the plurality of transistors is coplanar with a top surface of the first region and with the second surface.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF THE DRAWINGS

FIG. 1 is a diagrammatic representation of an example electron beam inspection (EBI) system, consistent with some embodiments of the present disclosure.

FIGS. 2A-C are diagrams illustrating charged particle beam apparatus that may be examples of an electron beam tool, consistent with some embodiments of the present disclosure.

FIG. 2D illustrates an electron arrival distribution on an example detector in a charged particle beam apparatus, consistent with some embodiments of the present disclosure.

FIGS. 3A-B are diagrammatic representations of example structures of a detector in a charged particle beam apparatus, consistent with some embodiments of the present disclosure.

FIG. 4 is a schematic diagram illustrating an example charged-particle detector with readout electronics, consistent with some embodiments of the present disclosure.

FIG. 5 is a schematic diagram illustrating an example simulation of a transistor with shallow-trench isolation in charged-particle detector, consistent with some embodiments of the present disclosure.

FIG. 6 is a schematic diagram illustrating an exemplary charged-particle detector having a substantially topology-less substrate, consistent with some embodiments of the present disclosure.

FIG. 7 is a flowchart illustrating an example method for manufacturing a substrate of a charged-particle detector, consistent with some embodiments of the present disclosure.

### DETAILED DESCRIPTION

Reference will now be made in detail to example embodiments, examples of which are illustrated in the accompanying drawings. The following description refers to the accompanying drawings in which the same numbers in different drawings represent the same or similar elements unless otherwise represented. The implementations set forth in the following description of example embodiments do not represent all implementations consistent with the disclosure. Instead, they are merely examples of apparatuses and methods consistent with aspects related to the subject matter recited in the appended claims. Without limiting the scope of the present disclosure, some embodiments may be described in the context of providing detection systems and detection methods in systems utilizing electron beams (“e-beams”). However, the disclosure is not so limited. Other types of charged-particle beams (e.g., including protons, ions, muons, or any other particle carrying electric charges) may be similarly applied. Furthermore, systems and methods for detection may be used in other imaging systems, such as optical imaging, photon detection, x-ray detection, ion detection, or any imaging system that may cause charging effects (that will be described in this disclosure).

Electronic devices are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them may be fit on the substrate. For example, an IC chip in a smartphone may be as small as a thumbnail and yet may include over 2 billion transistors, the size of each transistor being less than 1/1000th the size of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process; that is, to improve the overall yield of the process.

One component of improving yield is monitoring the chip-making process to ensure that it is producing a sufficient number of functional integrated circuits. One way to monitor the process is to inspect the chip circuit structures at various stages of their formation. Inspection may be carried out using a scanning charged-particle microscope (“SCPM”). For example, an SCPM may be a scanning electron microscope (SEM). A SCPM may be used to image these extremely small structures, in effect, taking a “picture” of the structures of the wafer. The image may be used to determine if the structure was formed properly in the proper location. If the structure is defective, then the process may be adjusted, so the defect is less likely to recur.

An image of a wafer may be formed by scanning one or more primary beams of a scanning charged-particle microscope (e.g., a “probe” beam) over the wafer and collecting particles (e.g., secondary electrons) generated from the wafer surface at a detector. Secondary electrons may form one or more secondary beams that are directed toward the detector. For each secondary beam, secondary electrons landing on the detector may cause electrical signals (e.g., current, charge, voltage, etc.) to be generated in the detector. These signals may be output from the detector and may be processed by an image processor to form the image of the sample.

Typically, the detection process involves measuring the magnitude of an electrical signal generated when electrons land on the detector. In another approach, electron counting may be used, in which a detector may count individual electron arrival events as they occur. In either approach, intensity of the secondary beam may be determined based on electrical signals generated in the detector that vary in proportion to the change in intensity of the secondary beam. Using electron counting, however, the discrete numbers of electrons that reach the detector from a beam of secondary electrons may be determined, and detection results may be output in digital form. The intensity of the beam may be determined by analyzing the frequency of electron arrival events.

Distortions exist in detection signals of the detector. One of the distortions is inter-symbol interference, which is a form of distortion of a symbol in an allotted time interval interfering with another symbol in another allotted time interval. For a detector of a charged-particle beam inspection apparatus, the inter-symbol inference occurs when some charged particles are delayed in arriving at sensing elements (e.g., diodes) of the detector within an allotted time interval, which may contribute to generation of a signal in a subsequent time interval. Similar to crosstalk, which is a form of signal interference in a space domain, the inter-symbol interference is a form of signal interference in a time domain.

Existing multi-beam inspection apparatuses typically use pixelated detectors for charged-particle detection. The pixelated detectors may include an array of diodes arranged on a layer as sensing elements, as well as a corresponding array of transistors arranged on another layer for signal pickup and processing. To prevent electric current leakage between adjacent diodes, an isolation technique referred to as shallow-trench isolation (“STI”) is used. A shallow trench may be created between two diodes by etching. The shallow trenches may form a pattern of trenches. A dielectric material (e.g., silicon-dioxide) layer may be deposited to fill the trenches with thickness of typically hundreds of nanometers. A dielectric material, as used herein, refers to a material or medium of electrical insulator that can be polarized by applying an electric field on it. The detector surface with STI applied has an uneven topology (referred to as “STI topology” herein).

However, when the detector having the STI topology is exposed to ion implantation, the dielectric material layer may be difficult for the implanted ions to penetrate for subsequent implantations. Both may cause lower implantation doses under areas covered by the shallow trenches, and further cause to form fixed charges near transistor channels of the detector when exposed to x-ray radiation. Such fixed charges may cause inter-symbol interference in the detector and may result in low quality inspection images.

Embodiments of the present disclosure may provide detectors with reduced inter-symbol interference. The substrate of the charged-particle detector, on one surface, may include a charge sensing element such as a diode, a photodiode, or other suitable charge sensing element. A plurality of transistors may be formed on a surface of the substrate opposite to the surface including the charge sensing element. One or more transistors of the plurality of transistors may be formed within a well region such that a top surface of each transistor of the plurality of transistors in the well region is coplanar with a top surface of the well region and with the surface on which the plurality of transistors is formed. Such a substrate may be used in a charged-particle detector, which may be in turn used in a charged-particle beam image inspection system.

Compared with existing charged-particle detectors that use STI or field oxide for isolation, the disclosed technical solutions herein provide various technical benefits. For example, because the top surfaces of the transistors on the first side and surfaces between the plurality of transistors on the first side are coplanar, the surface of the substrate layer may have great planarity, and dopants may be implanted into the substrate layer with a uniform penetration depth. Such a planar surface may help reduce or eliminate the possibility of formation of charge pockets. In the context of this disclosure, “charge pockets” refer to regions or areas with a higher or lower concentration of charges than adjacent coplanar regions. Also, because of the increased planarity of the surface of the substrate layer, electric potentials under the substrate layer may have a flat profile due to the uniform penetration depth of dopants and uniform dopant concentration, which may greatly reduce the inter-symbol interference, thereby improving image quality. Further, by not using STI or field oxide for isolation, x-rays are much less likely to create fixed charges when the detector is in a working status due to the uniform depth penetration of the implanted ions, which may provide better control of the transistors in the detector and render the transistors less susceptible to radiation damages caused by the x-rays.

Relative dimensions of components in drawings may be exaggerated for clarity. Within the following description of drawings, the same or like reference numbers refer to the same or like components or entities, and only the differences with respect to the individual embodiments are described.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

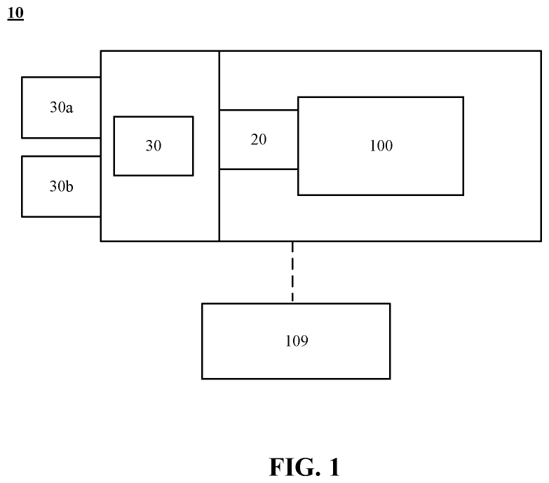

Reference is now made to FIG. 1, which illustrates an example electron beam inspection (EBI) system 10 that may be used for wafer inspection, consistent with some embodiments of the present disclosure. As shown in FIG. 1, EBI system 10 includes a main chamber 11 a load/lock chamber 20, an electron beam tool 100 (e.g., a scanning electron microscope (SEM)), and an equipment front end module (EFEM) 30. Electron beam tool 100 is located within main chamber 11 and may be used for imaging. EFEM 30 includes a first loading port 30a and a second loading port 30b. EFEM 30 may include additional loading ports. First loading port 30a and second loading port 30b receive wafer front opening unified pods (FOUPs) that contain wafers (e.g., semiconductor wafers or wafers made of other materials) or samples to be inspected (wafers and samples may be collectively referred to as “wafers” herein).

One or more robotic arms (not shown) in EFEM 30 may transport the wafers to load/lock chamber 20. Load/lock chamber 20 is connected to a load/lock vacuum pump system (not shown) which removes gas molecules in load/lock chamber 20 to reach a first pressure below the atmospheric pressure. After reaching the first pressure, one or more robotic arms (not shown) may transport the wafer from load/lock chamber 20 to main chamber 11. Main chamber 11 is connected to a main chamber vacuum pump system (not shown) which removes gas molecules in main chamber 11 to reach a second pressure below the first pressure. After reaching the second pressure, the wafer is subject to inspection by electron beam tool 100. Electron beam tool 100 may be a single-beam system or a multi-beam system. A controller 109 is electronically connected to electron beam tool 100, and may be electronically connected to other components as well. Controller 109 may be a computer configured to execute various controls of EBI system 10. While controller 109 is shown in FIG. 1 as being outside of the structure that includes main chamber 11, load/lock chamber 20, and EFEM 30, it is appreciated that controller 109 can be part of the structure.

A charged particle beam microscope, such as that formed by or which may be included in EBI system 10, may be capable of resolution down to, e.g., the nanometer scale, and may serve as a practical tool for inspecting IC components on wafers. With an e-beam system, electrons of a primary electron beam may be focused at probe spots on a wafer under inspection. The interactions of the primary electrons with the wafer may result in secondary particle beams being formed. The secondary particle beams may comprise backscattered electrons, secondary electrons, or Auger electrons, etc. resulting from the interactions of the primary electrons with the wafer. Characteristics of the secondary particle beams (e.g., intensity) may vary based on the properties of the internal or external structures or materials of the wafer, and thus may indicate whether the wafer includes defects.

The intensity of the secondary particle beams may be determined using a detector. The secondary particle beams may form beam spots on a surface of the detector. The detector may generate electrical signals (e.g., a current, a charge, a voltage, etc.) that represent intensity of the detected secondary particle beams. The electrical signals may be measured with measurement circuitries which may include further components (e.g., analog-to-digital converters) to obtain a distribution of the detected electrons. The electron distribution data collected during a detection time window, in combination with corresponding scan path data of the primary electron beam incident on the wafer surface, may be used to reconstruct images of the wafer structures or materials under inspection. The reconstructed images may be used to reveal various features of the internal or external structures or materials of the wafer and may be used to reveal defects that may exist in the wafer.

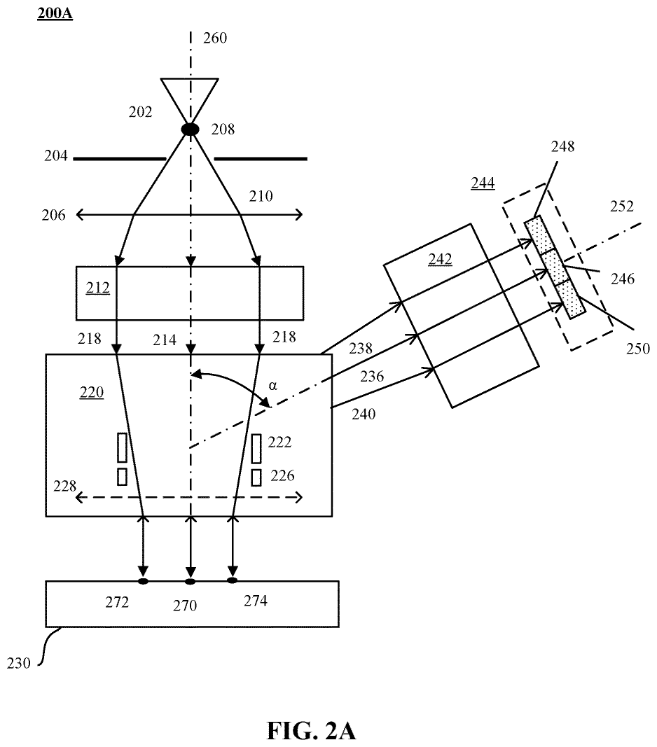

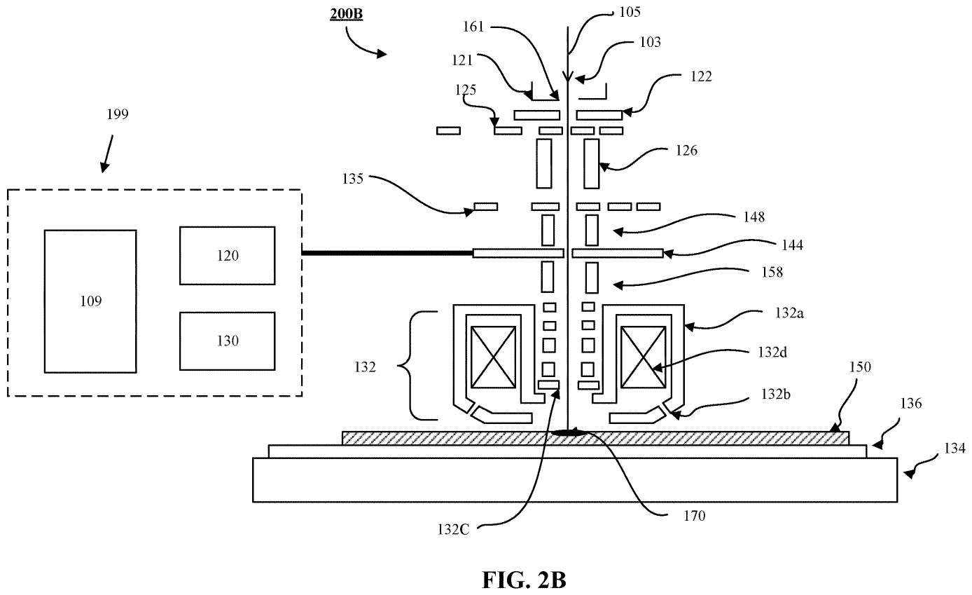

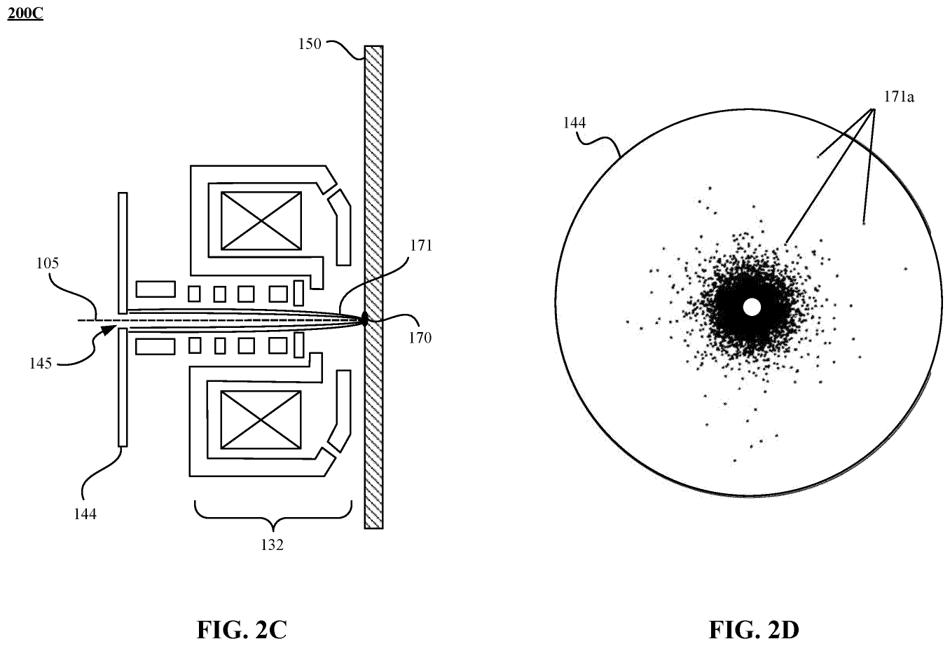

FIG. 2A illustrates an example of a charged particle beam apparatus that may be an example of electron beam tool 100, consistent with some embodiments of the present disclosure. Charged particle beam apparatus 200A may be a multi-beam tool that uses a plurality of beamlets formed from a primary electron beam to simultaneously scan multiple locations on a wafer.

As shown in FIG. 2A, electron beam tool 200A may comprise an electron source 202, a gun aperture 204, a condenser lens 206, a primary electron beam 210 emitted from electron source 202, a source conversion unit 212, a plurality of beamlets 214, 216, and 218 of primary electron beam 210, a primary projection optical system 220, a wafer stage (not shown in FIG. 2A), multiple secondary electron beams 236, 238, and 240, a secondary optical system 242, and electron detection device 244. Electron source 202 may generate primary particles, such as electrons of primary electron beam 210. A controller, image processing system, and the like may be coupled to electron detection device 244. Primary projection optical system 220 may comprise beam separator 222, deflection scanning unit 226, and objective lens 228. Electron detection device 244 may comprise detection sub-regions 246, 248, and 250.

Electron source 202, gun aperture 204, condenser lens 206, source conversion unit 212, beam separator 222, deflection scanning unit 226, and objective lens 228 may be aligned with a primary optical axis 260 of apparatus 200A. Secondary optical system 242 and electron detection device 244 may be aligned with a secondary optical axis 252 of apparatus 200A.

Electron source 202 may comprise a cathode, an extractor or an anode, wherein primary electrons can be emitted from the cathode and extracted or accelerated to form a primary electron beam 210 with a crossover (virtual or real) 208. Primary electron beam 210 can be visualized as being emitted from crossover 208. Gun aperture 204 may block off peripheral electrons of primary electron beam 210 to reduce size of probe spots 270, 272, and 274.

Source conversion unit 212 may comprise an array of image-forming elements (not shown in FIG. 2A) and an array of beam-limit apertures (not shown in FIG. 2A). An example of source conversion unit 212 may be found in U.S. Pat. No. 9,691,586; U.S. Publication No. 2017/0025243; and International Publication No. WO/2018122176, all of which are incorporated by reference in their entireties. The array of image-forming elements may comprise an array of micro-deflectors or micro-lenses. The array of image-forming elements may form a plurality of parallel images (virtual or real) of crossover 208 with a plurality of beamlets 214, 216, and 218 of primary electron beam 210. The array of beam-limit apertures may limit the plurality of beamlets 214, 216, and 218.

Condenser lens 206 may focus primary electron beam 210. The electric currents of beamlets 214, 216, and 218 downstream of source conversion unit 212 may be varied by adjusting the focusing power of condenser lens 206 or by changing the radial sizes of the corresponding beam-limit apertures within the array of beam-limit apertures. Condenser lens 206 may be an adjustable condenser lens that may be configured so that the position of its first principal plane is movable. The adjustable condenser lens may be configured to be magnetic, which may result in off-axis beamlets 216 and 218 landing on the beamlet-limit apertures with rotation angles. The rotation angles change with the focusing power and the position of the first principal plane of the adjustable condenser lens. In some embodiments, the adjustable condenser lens may be an adjustable anti-rotation condenser lens, which involves an anti-rotation lens with a movable first principal plane. An example of an adjustable condenser lens is further described in U.S. Publication No. 2017/0025241, which is incorporated by reference in its entirety.

Objective lens 228 may focus beamlets 214, 216, and 218 onto a wafer 230 for inspection and may form a plurality of probe spots 270, 272, and 274 on the surface of wafer 230. Secondary electron beamlets 236, 238, and 240 may be formed that are emitted from wafer 230 and travel back toward beam separator 222.

Beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. Beam separator 222 may separate secondary electron beams 236, 238, and 240 from beamlets 214, 216, and 218 and direct secondary electron beams 236, 238, and 240 towards secondary optical system 242.

Deflection scanning unit 226 may deflect beamlets 214, 216, and 218 to scan probe spots 270, 272, and 274 over an area on a surface of wafer 230. In response to incidence of beamlets 214, 216, and 218 at probe spots 270, 272, and 274, secondary electron beams 236, 238, and 240 may be emitted from wafer 230. Secondary electron beams 236, 238, and 240 may comprise electrons with a distribution of energies including secondary electrons and backscattered electrons. Secondary optical system 242 may focus secondary electron beams 236, 238, and 240 onto detection sub-regions 246, 248, and 250 of electron detection device 244. Detection sub-regions 246, 248, and 250 may be configured to detect corresponding secondary electron beams 236, 238, and 240 and generate corresponding signals used to reconstruct an image of the surface of wafer 230. Detection sub-regions 246, 248, and 250 may include separate detector packages, separate sensing elements, or separate regions of an array detector. In some embodiments, each detection sub-region may include a single sensing element.

FIG. 2B illustrates another example of a charged particle beam apparatus, consistent with some embodiments of the present disclosure. Electron beam tool 200B (also referred to herein as apparatus 200B) may be an example of electron beam tool 100. Electron beam tool 200B may be similar to electron beam tool 200A shown in FIG. 2A. However, different from apparatus 200A, apparatus 200B may be a single-beam tool that uses one primary electron beam to scan one location on the wafer at a time.

As shown in FIG. 2B, apparatus 200B includes a wafer holder 136 supported by motorized stage 134 to hold a wafer 150 to be inspected. Electron beam tool 200B includes an electron emitter, which may comprise a cathode 103, an anode 121, and a gun aperture 122. Electron beam tool 200B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector 132c, and an exciting coil 132d. In a detection or imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector 132c or other deflectors in the SORIL lens. Secondary or scattered particles, such as secondary electrons or scattered primary electrons emanated from the wafer surface may be collected by detector 144 to determine intensity of the beam and so that an image of an area of interest on wafer 150 may be reconstructed.

It is appreciated that electron beam tools 200A and 200B may include an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may connect with detector 144 of electron beam tool 200B through a medium such as an electrical conductor, optical fiber cable, portable storage media, IR, Bluetooth, internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as image averaging, generating contours, superimposing indicators on an acquired image, and the like. Image acquirer 120 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 200B may comprise a first quadrupole lens 148 and a second quadrupole lens 158. In some embodiments, the quadrupole lenses may be used for controlling the electron beam. For example, first quadrupole lens 148 may be controlled to adjust the beam current and second quadrupole lens 158 may be controlled to adjust the beam spot size and beam shape.

In some embodiments of the disclosure, a PIN detector may be used as an in-lens detector in a retarding objective lens SEM column of EBI system 10. The PIN detector may be placed between a cathode for generating an electron beam and the objective lens. The electron beam emitted from the cathode may be potentialized at −BE keV (typically around −10 kV). Electrons of the electron beam may be immediately accelerated and travel through the column. The column may be at ground potential. Thus, electrons may travel with kinetic energy of BE keV while passing through opening 145 of detector 144. Electrons passing through the pole piece of the objective lens, such as pole piece 132a of objective lens assembly 132 of FIG. 2B, may be steeply decelerated down to landing energy LE keV as the wafer surface potential may be set at (BE−LE) keV.

FIG. 2C illustrates an example of a charged particle beam apparatus 200C, consistent with some embodiments of the present disclosure. Charged particle beam apparatus 200C may be, e.g., charged particle beam apparatus 200A of FIG. 2A or 200B of FIG. 2B. Emitted electrons 171, comprising e.g., secondary or backscattered electrons, are emitted from the wafer surface by the impingement of electrons of the primary electron beam 105. A retarding electric field, which may slow the primary electrons as they approach probe spot 170, may act as an acceleration electric field to accelerate the emitted electrons backwards toward a PIN detector 144 surface. For example, as shown in FIG. 2C, due to interactions with wafer 150 at probe spot 170, emitted electrons 171 may be generated that travel back toward detector 144. Emitted electrons 171 from the wafer surface travelling along optical axis 105 may arrive at the surface of detector 144 with a distribution of positions. The landing positions of emitted electrons may be within a generally circular region with a radius of, for example, a few millimeters. A geometric spread of landing positions of emitted electrons may be due to electrons having different trajectories that may be dependent on, for example, initial kinetic energy and emission angles of the electrons. Other factors may affect a geometric spread, or other characteristics, of landing positions. These factors are discussed below with respect to embodiments of the present disclosure.

FIG. 2D illustrates an example of an emitted electron landing point distribution on a detector surface. Electrons 171a may land at different points on the surface of detector 144 while, generally, most may be clustered around the central portion of detector 144 when there is no deflection field. As discussed above, emitted electrons may comprise, e.g., secondary or backscattered electrons. In some embodiments, for example, a distribution may comprise between 60-85% secondary electrons and between 40-15% backscattered electrons. The landing point distribution may shift depending on emission position and SEM deflection fields (e.g., scan field). Therefore, in some applications, if a certain field of view (FOV) of a SEM image is required, the required size of an in-lens PIN detector may be substantially large. Typically, a detector may be 10 mm in diameter, or larger, for example. In some embodiments, a detector may be, e.g., about 4 to 10 mm in diameter.

Detector 144 may be placed along optical axis 105. The primary electron beam may be configured to travel along optical axis 105. Accordingly, detector 144 may include a hole 145 at its center so that the primary electron beam may pass through to reach wafer 150. FIGS. 2B-C show examples of a detector 144 having an opening at its center. However, some embodiments may use a detector placed off-axis relative to the optical axis along which the primary electron beam travels. For example, as in the example shown in FIG. 2A, a beam separator 222 may be provided to direct emitted electron beams toward a detector placed off-axis. Beam separator 222 may be configured to divert emitted electron beams by an angle a toward an electron detection device 244, as shown in FIG. 2A. Therefore, in some embodiments of the present disclosure, a detector may be provided that has no central opening.

Detectors 244 of FIG. 2A or 144 of FIGS. 2B-D or may include sensing elements such as diodes, or elements similar to diodes, that may convert incident energy into a measurable signal. For example, sensing elements in a detector may include a single-photon avalanche diode (SPAD), an avalanche photodiode (APD), or a PIN diode. Throughout this disclosure, sensing elements may be represented as a diode, although sensing elements or other components may deviate from ideal circuit behavior of electrical elements such as diodes, resistors, capacitors, etc. In embodiments of the present disclosure, a detector in a charged particle beam system may comprise a pixelated array of multiple sensing elements. The sensing elements may be configured for charged particle counting. Sensing elements of a detector that may be useful for charged particle counting are discussed in U.S. Publication No. 2019/0378682, which is incorporated by reference in its entirety.

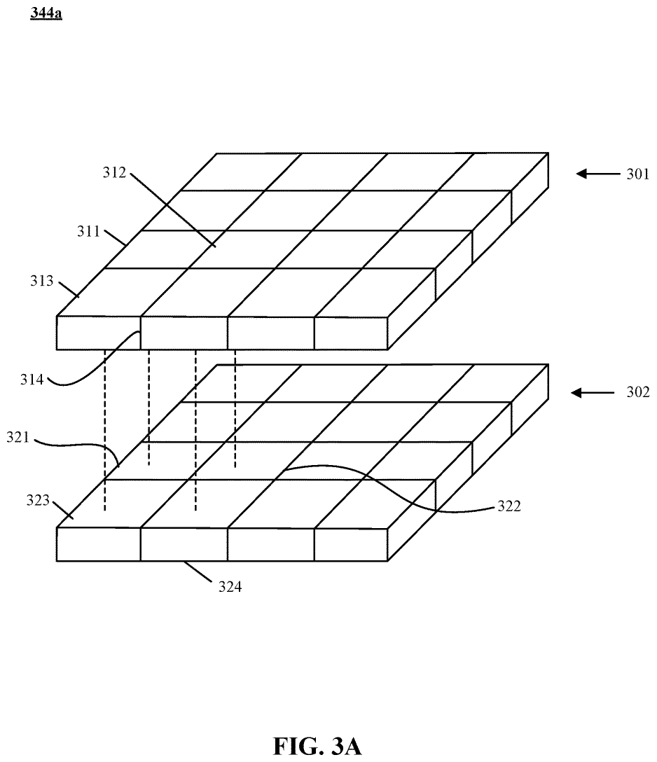

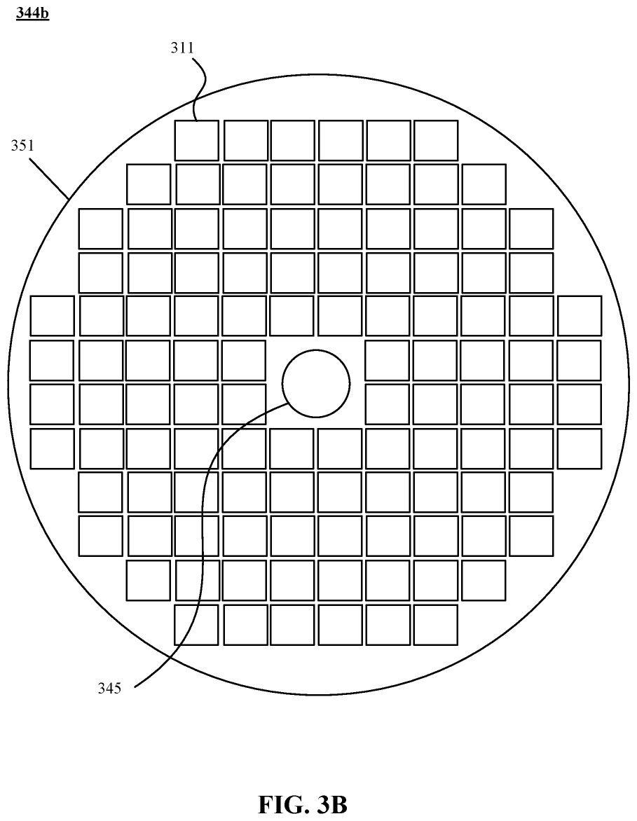

FIGS. 3A-B illustrate example structures of a pixelated electron counting detector (PECD), consistent with some embodiments of the present disclosure. A detector such as detector 344a of FIG. 3A or 344b of FIG. 3B may be provided as detector 244 as shown in FIG. 2A or 144 as shown in FIGS. 2B-D. In FIG. 3A, detector 344a includes a sensor layer 301 and a signal processing layer 302. Sensor layer 301 may include a sensor die made up of multiple sensing elements, including sensing elements 311, 312, 313, and 314. In some embodiments, the multiple sensing elements may be provided in an array of sensing elements, each of which may have a uniform size, shape, and arrangement.

Signal processing layer 302 may include multiple signal processing circuits, including circuits 321, 322, 323, and 324. The circuits may include interconnections (e.g., wiring paths) configured to communicatively couple sensing elements. Each sensing element of sensor layer 301 may have a corresponding signal processing circuit in signal processing layer 302. Sensing elements and their corresponding circuits may be configured to operate independently. As shown in FIG. 3A, circuits 321, 322, 323, and 324 may be configured to communicatively couple to outputs of sensing elements 311, 312, 313, and 314, respectively, as shown by the four dashed lines between sensor layer 301 and signal processing layer 302.

In some embodiments, signal processing layer 302 may be configured as a single die with multiple circuits provided thereon. Sensor layer 301 and signal processing layer 302 may be in direct contact. In some embodiments, components and functionality of different layers may be combined or omitted. For example, signal processing layer 302 may be combined with sensor layer 301 into a single layer. Furthermore, a circuit for charged particle counting may be integrated at various points in a detector, for example in a separate read-out layer of a detector or on a separate chip. Further details of electron counting circuitry and alternative structures for sensor layer 301 and signal processing layer 302 may be found in International Publication WO 2022/008518, the entirety of which is incorporated herein by reference.

As shown in FIG. 3B, a detector 344b having an array of sensing elements 311 may be provided. Detector 344b may be, e.g., a photoelectrochemical detector (PECD). Detector 344b may include sensor layer 301 and signal processing layer 302 as seen in FIG. 3A. Detector circuitry may include an electron counting circuit separately provided for each sensing element. Detector 344b may include a plate 351, wherein the plurality of sensing elements 311 are formed thereon. Plate 351 may include opening 345 for allowing a primary electron beam to pass through plate 351.

When an individual sensing element 311 of a detector is made small compared to the geometric spread of emitted electrons incident on the detector, individual electron counting may be achieved. For example, each sensing element may have its own counting unit comprising circuitries configured to measure an output signal from the sensing element. When sensing elements are made smaller, the rate of electron arrival at each sensing element is reduced, and thus electron counting at each sensing element may become enabled. Furthermore, the capacitance of a detector may be proportional to an area of a detector surface. Some sources of noise, such as that due to components being coupled to a detector (e.g., an amplifier), may be related to capacitance. The small area of each individual element in a photoelectrochemical detector allows a much lower capacitance than, e.g., a large continuous sensing surface. For example, an individual sensing element may be a square or other shape having dimensions of, e.g., 5, 10, 25, 50, 100, 200, or 300 μm on a side. Sensing elements may be larger, e.g., on the order of millimeters. A typical detector may comprise, e.g., 100, 500, 1,000, 5,000, 10,000, 50,000 or 100,000 or more sensing elements.

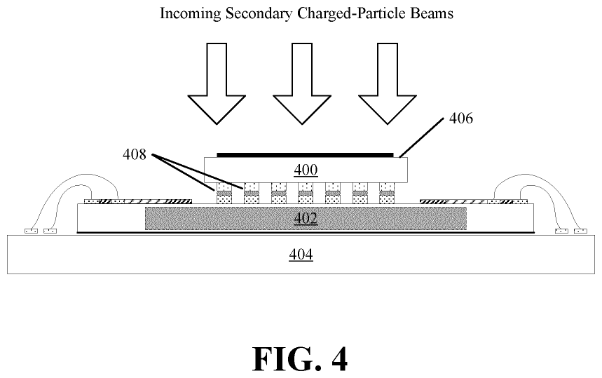

By way of example, FIG. 4 is a schematic diagram illustrating an example charged-particle detector 400 with readout electronics 402, consistent with some embodiments of the present disclosure. In some embodiments, detector 400 may be used in detector 344a in FIG. 3A or in detector 344b in FIG. 3B. In some embodiments, detector 400 may be used as electron detection device 244 in electron beam tool 200A of FIG. 2A. In some embodiments, detector 400 may be used as detector 144 in electron beam tool 200B of FIG. 2B. In some embodiments, readout electronics 402 may include signal processing layer 302 illustrated and described in association with FIG. 3A.

As illustrated in FIG. 4, detector 400 may have a surface 406 that may receive secondary charged particle beams (represented by downward arrows in FIG. 4) from an image inspection apparatus. Multiple sensing elements (representing by a thick solid line on top of surface 406) may be formed on surface 406 for receiving and facilitate detection of the secondary charged particle beams. Underneath the sensing elements, detector 400 may further include a switching matrix (not shown in FIG. 4) for switching on or off the sensing elements. In some embodiments, switches in the switching matrix may be implemented using transistors (e.g., NMOS, PMOS). Readout electronics 402 may be electrically coupled to detector 400 via multiple bonding parts 408 (represented by multiple cylinders in FIG. 4). In some embodiments, bonding parts 408 may include interconnections (e.g., wiring paths) between sensing elements and signal processing circuits, such as the interconnections described in association with FIG. 3A.

Output signals of readout electronics 402 may be further output to a computer or processor (not shown in FIG. 4) for further signal processing. As illustrated in FIG. 4, readout electronics 402 may be positioned on a base 404. For example, base 404 may be plate 351 as illustrated and described in association with FIG. 3B.

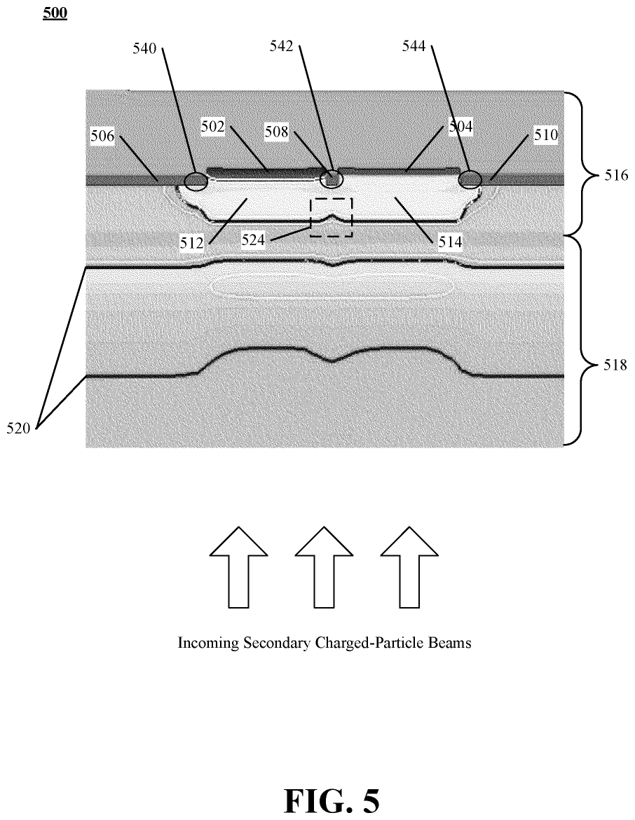

By way of example, FIG. 5 is a schematic diagram illustrating an example simulation of a transistor with shallow-trench isolation in a charged-particle detector, consistent with some embodiments of the present disclosure. For example, detector 500 may be an implementation of detector 400 of FIG. 4. Detector 500 may include multiple complementary metal oxide semiconductor (CMOS) transistors that further include a NMOS transistor 502 (e.g., a N-type metal-oxide semiconductor) and a PMOS transistor 504 (e.g., a P-type metal-oxide semiconductor). To electrically isolate N-type transistor 502 and P-type transistor 504, multiple trenches are created using shallow-trench isolation (STI) techniques between NMOS transistor 502 and PMOS transistor 504, including STI trenches 506, 508, and 510. STI trenches 506, 508, and 510 may be formed using dielectric materials such as, but not limited to, silicon dioxide, silicon nitride, silicon oxynitride, among other suitable dielectric materials. For example, STI trenches 506, 508, and 510 may be formed by depositing or forming a silicon-dioxide layer (SiO₂) layer having a thickness of 10 nm or more, or 50 nm or more, or 100 nm or more, or 500 nm or more, or other suitable thicknesses.

As illustrated in FIG. 5, NMOS transistor 502 is formed in a P-type well (“P-well”) 512, and PMOS transistor 504 is formed in an N-type well (“N-well”) 514. NMOS transistor 502, PMOS transistor 504, STI trenches 506, 508, and 510, P-well 512, and N-well 514 may all be formed inside an implant layer 516 (e.g., an N-type implant layer). Implant layer 516 may be in direct contact with a substrate layer 518 (e.g., a silicon layer). In some embodiments, substrate layer 518 may be a high resistivity substrate with low doping concentrations e.g., 10¹³ atoms/cm3 or less, and implant layer 516 may be doped with a doping concentration of 10¹³ atoms/cm³ or more. Both implant layer 516 and substrate layer 518 may be inside detector 500, in which substrate layer 518 may extend to a surface of detector 500 (e.g., surface 406 illustrated in FIG. 4).

As illustrated in FIG. 5, detector 500 may receive secondary charged particle beams (represented by upward arrows in FIG. 5) from an electron beam inspection apparatus. Sensing elements (not shown in FIG. 5) of detector 500 may facilitate detection of the secondary charged particle beams, and secondary charged particles of the secondary charged particle beams may enter substrate layer 518 (e.g., in an upward direction) and create charge carrier pairs (e.g., electron-hole pairs). The charge carrier pairs may be biased by an external electric field, and carriers with the same charge-type (e.g., negative charge type) may move towards the implant layer 516. The circuit formed from multiple NMOS and PMOS transistors may further collect, amplify, and convert the charge carrier pairs into a detection signal, and further output the detection signal to a corresponding bonding part (e.g., one of bonding parts 408 illustrated in FIG. 4). The bonding part may further route the detection signal to readout electronics (e.g., readout electronics 402 in FIG. 4). During this process, an internal electric field may be formed inside the detector. As illustrated in FIG. 5, potential equilibrium lines 520 show equipotential lines of the internal electric field inside detector 500.

The NMOS or PMOS transistors illustrated in FIG. 5 may be switched on or off by switching on or off (e.g., by switching transistor gates) at least one of NMOS transistor 502 or PMOS transistor 504. If the transistor is switched off, by design, the transistor will not output any detection signal to its corresponding bonding part. By doing so, a sensing element corresponding to the transistor (e.g., any of sensing elements 311, 312, 313, or 314 illustrated in FIG. 3A) may be disabled, and an area of detector 500 (e.g., referred to as a “pixel”) corresponding to the sensing element may be deselected for charged particle detection.

However, it has been identified that the STI isolation (e.g., STI trenches 506, 508, and 510) in detector 500 may cause several technical challenges, some of which are illustrated in FIG. 5. For example, permittivity of the NMOS transistor 502, PMOS transistor 504, and STI trenches 506, 508, and 510 may be different. When the incoming secondary charged-particle beam in FIG. 5 (e.g., accelerated electrons) passes through the substrate, the charge carriers may be decelerated and incur Bremsstrahlung radiation (e.g., x-rays). Such Bremsstrahlung radiation may irradiate STI trenches 506, 508, and 510 and create fixed positive charges in the STI trenches. For example, if the charge carriers are electrons, the Bremsstrahlung radiation may create positive charges near regions of STI trenches 506, 508, and 510. Such positive charges may form a charge buildup, referred to as “fixed charges,” illustrated as 540, 542, and 544 in FIG. 5.

Fixed charges 540, 542, and 544 may interfere with the functionality of detector 500 in several ways. For example, fixed charges 540 and 542 may increase conductivity of regions where NMOS transistor 502 is near to one or more STI trenches (e.g., STI trenches 506 or 508). If NMOS transistor 502 is switched off by switching off its gate, charges may still keep moving in NMOS transistor 502. Effectively, NMOS transistor 502 may not be completely switched off due to fixed charges 540 and 542. In such a case, the pixel corresponding to NMOS transistor 502 cannot be deselected, and the pixel may continue to produce a detection signal even when there is no secondary charged particle beam landing on it. Such an interference may eventually cause undesirable blurring in a resultant inspection image.

As another example, fixed charges 540 and 542 may interfere with the functionality of detector 500 even when NMOS transistor 502 is switched on. If detector 500 runs for a prolonged period, NMOS transistor 502 may be switched between an “on” status and an “off” status for many times. When the pixel corresponding to NMOS transistor 502 is selected, a first secondary charged particle beam may land on the pixel and add charges to fixed charges 540 and 542. After that, when a second secondary charged particle beam lands on the pixel, fixed charges 540 and 542 may not have been depleted yet. Such fixed charges may be superposed with charge carriers caused by the second secondary charged particle beam and distort its detection signal (e.g., by increasing or decreasing its amplitude or charge particle counts). Such a distortion is a form of inter-symbol interference, which may in turn cause undesirable blurring in the resultant inspection image.

In another example, it has been recognized that fixed charge 544 may decrease conductivity of regions where PMOS transistor 504 is near to one or more STI trenches (e.g., STI trenches 508 or 510). Such decreased conductivity may increase isolation of PMOS transistor 504.

In another example, it has been recognized that the STI isolation in detector 500 may affect implantation of implant layer 516 during a manufacturing process of detector 500. Typically, the STI isolation is implemented after forming the CMOS transistor and before doping implant layer 516. However, due to the uneven topography created by the STI isolation (e.g., illustrated by FIG. 5 in which NMOS transistor 502, PMOS transistor 504, and STI trenches 506, 508, and 510 are not coplanar), mechanical stress may form near the STI trenches. Such mechanical stress may affect mobility of charge carriers (e.g., dopants). Also, because STI trenches may be formed from dielectric materials, it may be more difficult for charge carriers to penetrate through. The mechanical stress and the dielectric characteristics of STI trenches may cause a shielding effect that may lower implantation doses in regions near an STI trench. The lowered implantation doses may subsequently cause non-uniform doping of implant layer 516. By way of example, such a non-uniformity in doping profile may be represented by a tip 524 in FIG. 5. The non-uniform doping of implant layer 516 may further affect functionality and performance of detector 500.

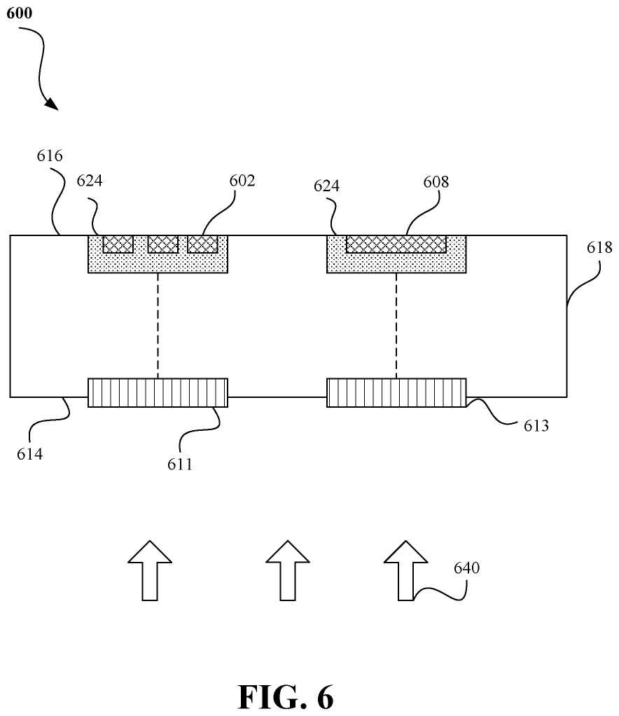

To mitigate one or more of the identified challenges, a substrate for a charged-particle detector is disclosed herein. Reference is now made to FIG. 6, which illustrates a schematic illustration of an exemplary charged particle detector 600 having a substrate comprising a substantially topology-less surface, consistent with some embodiments of the present disclosure. In the context of this disclosure, a “substantially topology-less” surface of a substrate refers to a surface which is substantially planar or substantially free from protrusions or recessions caused by depositions on the substrate, creation of trenches in the substrate, or oxidation of the substrate, or any other fabrication step that may create penetration differences for implantations during fabrication of the detector. After the implantation process, processing steps such as, but not limited to, deposition of silicon or other materials, oxidation of the substrate, or etching to create trenches may be performed. In some embodiments, a substantially topology-less surface may include protrusions having a maximum height of 5 nm or less, 4 nm or less, 3 nm or less, 2 nm or less, 1 nm or less, or 0.5 nm or less and recessions having a maximum depth of 5 nm or less, 4 nm or less, 3 nm or less, 2 nm or less, 1 nm or less, or 0.5 nm or less.

Detector 600 may include a substrate layer 618 having a first surface 614 and a second surface 616. In the context of this disclosure, a “first surface” or a “front surface” refers to a surface of the substrate on which the incoming secondary charged particles are incident, and a “second surface” or a “rear surface” refers to a surface of the substrate opposite the first surface. In some embodiments, substrate layer 618 may be located such that rear surface 616 may be downstream from front surface 614. As used in the context of this disclosure, “downstream” refers to a position of an element or a surface located below or after another element or surface, along the path of secondary charged-particle beam 640 (e.g., secondary charged-particle beams 236, 238, 240 of FIG. 2A) originating from the sample. Substrate layer 618 may comprise a silicon substrate layer. The silicon substrate layer may be an intrinsic or a lightly doped (e.g., doping concentration<10¹³ atoms/cm³) substrate having high resistivity. In some embodiments, substrate layer 618 may comprise a semiconductor material including, but not limited to, Silicon (Si), Germanium (Ge), Silicon-Germanium (SiGe), Gallium Arsenide (GaAs), Indium Gallium Arsenide (InGaAs), or other suitable substrate material.

In some embodiments, detector 600 may comprise charge sensing elements 611 and 613 formed on first surface 614 of substrate layer 618. In some embodiments, the charge sensing elements may include a diode (e.g., a SPAD, an APD, or a PIN diode). By way of example, charge sensing element 611 or 613 may be sensing element 311 illustrated and described in association with FIGS. 3A-B. In some embodiments, the disclosed substrate may include multiple charge sensing elements formed on first surface 614. The multiple charge sensing elements may form sensor dies, and the sensor dies may further form a sensor layer (e.g., sensor layer 301 illustrated and described in association with FIG. 3A).

In some embodiments, detector 600 may comprise a plurality of transistors 602, 608, formed on second surface 616 of substrate layer 618. The plurality of transistors may include at least one of an NMOS transistor or a PMOS transistor. In some embodiments, the plurality of transistors may include a CMOS (e.g., the CMOS illustrated and described in association with FIG. 5). As illustrated in FIG. 6, one or more transistors 602 may be formed inside substrate layer 618 such that a top surface of transistor 602 is coplanar with second surface 616. In some embodiments, substrate layer 618 may include a plurality of doped regions 624. One or more transistors 602 may be formed inside doped region 624 such that a top surface of transistor 602 may be coplanar with a top surface of doped region 624 and second surface 616 of substrate layer 618.

In some embodiments, transistor 602 may be a NMOS transistor and doped region 624 may be a p-well region doped with a p-type dopant such as, but not limited to, boron, gallium, among other dopants. In some embodiments, transistor 608 may be a CMOS transistor, including a combination of a NMOS transistor and a PMOS transistor, formed inside doped region 624.

Consistent with some embodiments of this disclosure, doped regions 624 may provide a conductive isolation well, formed on the second surface 616 inside substrate layer 618. The conductive isolation well, implemented by a p-well, for example, may be configured to electrically isolate a transistor (e.g., NMOS transistor) of the plurality of transistors. In some embodiments, the conductive isolation well (e.g., doped regions 624) may form one or more P-N junctions with NMOS transistors.

By way of example, the conductive isolation well may be formed using a junction isolation technique, without using any STI isolation. A conductive isolation well, as used herein, refers to an isolation well formed by electrically conducting materials such as a doped semiconductor, or an extrinsic semiconductor. In some embodiments, for a transistor formed on second surface 616 of the substrate layer 618, impurities or dopants may be implanted into surrounding regions of the transistor to form a P-N junction. The formed P-N junction may provide a conductor. When the formed P-N junction is reverse biased (e.g., by a bias voltage), an isolation well may be formed around the transistor, and the transistor may be electrically isolated by the formed isolation well. Dissimilar to the isolation well formed by an STI trench, which is formed by dielectric materials (e.g., oxides or nitrides), the isolation well formed by the biased P-N junction may be made of electrically conducting materials.

In some embodiments, one or more transistors 602 may be configured to activate, deactivate, control, or communicate with charge sensing elements 611 and 613. In some embodiments, a single transistor may be configured to activate, deactivate, control, or communicate with a corresponding charge sensing element. Alternatively, or additionally, a plurality of transistors may activate, deactivate, or communicate with a single charge sensing element. In the context of this disclosure, activating a charge sensing element refers to enabling a charge sensing element, by a switching functionality provided by a transistor, to detect charged particles. Deactivating a charge sensing element refers to disabling the charge sensing element, by switching the transistor off, from detecting charged particles incident on the charge sensing element.

It has been recognized that, in the realm of fabrication of semiconductor devices with shrinking geometries, junction isolation techniques may not be a preferred isolation technique because of the large dimensions and larger space occupied in comparison with STI techniques. The formation of large, doped regions or isolation wells in which one or more transistors are formed may be counter-productive towards the effort to achieve high device density on an IC chip with sub-100 nm technology nodes. However, it has been recognized that, for charged-particle detectors having dimensions in the scale of hundreds of micrometers (e.g., 100, 200, 300 micrometers or the like) and low circuitry complexity, junction isolation techniques may not introduce area penalty and may be desirable.

The disclosed substrate may have several advantages compared with existing STI isolation techniques. As described in the example embodiments of this disclosure, because the top surfaces of the plurality of transistors and the surface between the transistors is coplanar, unlike detectors with STI isolation applied, the disclosed substrate may have a flat topology on its surface, and thus less mechanical stress may be caused in the regions near the plurality of transistors. In such cases, mobility of charge carriers is less likely to be affected by such mechanical stress, and electric potentials inside the substrate layer may have a flat profile. Eventually, the likelihood of fixed charges formation may be greatly reduced or eliminated. With reduced or eliminated fixed charges, the inter-symbol interference in the detector may be greatly suppressed, and clarity of resulted inspection images may be greatly improved.

In some embodiments, forming a conductive isolation well using junction isolation techniques may mitigate the occurrence of Bremsstrahlung radiation when charged particles pass through it, which may reduce the likelihood of fixed charges (e.g., fixed charges 540, 542, and 544 of FIG. 5) formation in substrate layer 618. Also, because of the conductive material of the isolation well, compared to the dielectric material in STI isolation, charge carriers may easily penetrate the conductive isolation well of the disclosed substrate, and thus reduce or eliminate the shielding effect. During manufacturing of the detector, the reduced or eliminated shielding effect may help form a uniform doping profile of the implant layer (e.g., implant layer 516 of FIG. 5) of the detector, which may further improve functionality and performance of the detector.

Consistent with some embodiments of this disclosure, the disclosed substrate may be used in a charged-particle detector (e.g., electron detection device 244 in electron beam tool 200A of FIG. 2A or detector 144 in electron beam tool 200B of FIG. 2B). Consistent with some embodiments of this disclosure, the disclosed substrate may be used in a charged-particle detector that may further be used in an image inspection apparatus (e.g., electron beam tool 200A of FIG. 2A or electron beam tool 200B of FIG. 2B).

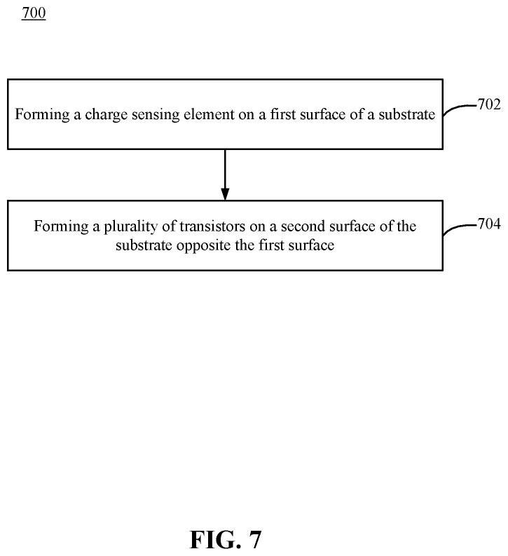

Consistent with some embodiments of this disclosure, a method for manufacturing a substrate for a charged-particle detector is disclosed. By way of example, FIG. 7 is a flowchart illustrating an exemplary method 700 for manufacturing the substrate for a charged-particle detector in a charged-particle beam apparatus.

At step 702, a sensing element (e.g., sensing element 311 illustrated and described in association with FIG. 3A or charge sensing element 611 of FIG. 6) may be formed on a first surface (e.g., first surface 614 of FIG. 6). In some embodiments, the sensing element may include a diode (e.g., a SPAD, an APD, or a PIN diode). The substrate layer may include a first surface and a second surface (e.g., second surface 616 of FIG. 6). The first surface may be configured to receive secondary charged particles originating from a sample. The second surface may be opposite to the first surface. In some embodiments, the substrate layer may include a silicon layer (e.g., substrate layer 518 illustrated and described in association with FIG. 5).

At step 704, a plurality of transistors may be formed on the second surface of substrate layer. The plurality of transistors may include at least one of a NMOS transistor or a PMOS transistor. In some embodiments, the plurality of transistors may include a CMOS (e.g., the CMOS illustrated and described in association with FIG. 5). One or more transistors (e.g., transistor 602 of FIG. 6) may be formed inside the substrate layer such that a top surface of the transistor is coplanar with the second surface. In some embodiments, the substrate layer may include a plurality of doped regions (e.g., doped region 624 of FIG. 6). One or more transistors may be formed inside doped region such that a top surface of the transistor may be coplanar with a top surface of the doped region and with the second surface of substrate layer.

In some embodiments, the plurality of transistors may include a plurality of N-type transistors. In some embodiments, the plurality of N-type transistors may include a plurality of N metal oxide semiconductor (NMOS) transistors. In some embodiments, when the plurality of transistors includes the plurality of N-type transistors, method 700 may further include a step of forming a p-type doped region (e.g., p-well 512 illustrated and described in association with FIG. 5 or doped region 624 of FIG. 6) on the second surface inside the substrate layer.

The embodiments can further be described using the following clauses:
1. A substrate for a charged-particle detector, the substrate comprising:
a charge sensing element formed on a first surface of the substrate and configured to detect charged particles originating from a sample; and
a plurality of transistors formed in a first region of a second surface of the substrate, the second surface being opposite the first surface,
wherein a top surface of each transistor of the plurality of transistors is coplanar with a top surface of the first region and with the second surface of the substrate.
2. The substrate of clause 1, wherein the charge sensing element comprises a diode, a photodiode, a single-photon avalanche diode, or an avalanche photodiode.
3. The substrate of any one of clauses 1 and 2, wherein the plurality of transistors comprises a plurality of n-type metal oxide semiconductor (NMOS) transistors or a plurality of p-type metal oxide semiconductor (PMOS) transistors.
4. The substrate of any one of clauses 1 and 3, wherein the first region comprises a p-type well formed inside the substrate such that a top surface of the p-type well is coplanar with the second surface of the substrate.
5. The substrate of any one of clauses 1 and 4, wherein the first region comprises a conductive isolation well formed inside the substrate such that a top surface of the p-type well is coplanar with the second surface of the substrate.
6. The substrate of clause 5, wherein the conductive isolation well forms a p-n junction with a transistor of the plurality of transistors.
7. The substrate of any one of clauses 1-6, wherein the second surface is downstream from the first surface with respect to a path of the charged particles.
8. The substrate of any one of clauses 1-7, wherein the second surface comprises a substantially topology-less surface.
9. The substrate of any one of clauses 1-8, wherein transistors of the plurality of transistors are isolated from each other by junction isolation.
10. The substrate of clause 9, wherein transistors of the plurality of transistors are isolated from each other without a dielectric or a shallow trench isolation (STI).
11. A charged-particle detector, comprising:
a substrate layer comprising a first surface and a second surface opposite the first surface;
a charge sensing element formed on the first surface and configured to detect charged particles originating from a sample; and
a plurality of transistors formed in a first region of the second surface of the substrate layer,
wherein a top surface of each transistor of the plurality of transistors is coplanar with a top surface of the first region and the second surface of the substrate layer.
12. The charged-particle detector of clause 11, wherein the charge sensing element comprises a diode, a photodiode, a single-photon avalanche diode, or an avalanche photodiode.
13. The charged-particle detector of any one of clauses 11 and 12, wherein the plurality of transistors comprises a plurality of n-type metal oxide semiconductor (NMOS) transistors or a plurality of p-type metal oxide semiconductor (PMOS) transistors.
14. The charged-particle detector of any one of clauses 11-13, wherein the first region comprises a p-type well formed inside the substrate such that a top surface of the p-type well is coplanar with the second surface of the substrate layer.
15. The charged-particle detector of any one of clauses 11-14, wherein the first region comprises a conductive isolation well formed inside the substrate such that a top surface of the p-type well is coplanar with the second surface of the substrate layer.
16. The charged-particle detector of clause 15, wherein the conductive isolation well forms a p-n junction with a transistor of the plurality of transistors.
17. The charged-particle detector of any one of clauses 11-16, wherein the second surface is downstream from the first surface with respect to a path of the charged particles.
18. The charged-particle detector of any one of clauses 11-17, wherein the second surface comprises a substantially topology-less surface.
19. The charged-particle detector of any one of clauses 11-18, wherein transistors of the plurality of transistors are isolated from each other by junction isolation.
20. The charged-particle detector of clause 19, wherein transistors of the plurality of transistors are isolated from each other without a dielectric or a shallow trench isolation (STI).
21. A charged-particle beam apparatus, comprising:
a charged-particle source configured to emit primary charged particles to be incident on a sample; and
a charged-particle detector configured to detect secondary charged particles generated from the sample upon interaction with the primary charged particles, the charged-particle detector comprising:
a substrate layer comprising a first surface and a second surface opposite the first surface;
a charge sensing element formed on the first surface and configured to detect charged particles originating from a sample; and
a plurality of transistors formed in a first region of the second surface of the substrate layer,
wherein a top surface of each transistor of the plurality of transistors is coplanar with a top surface of the first region and with the second surface of the substrate layer.
22. The charged-particle beam apparatus of clause 21, wherein the charge sensing element comprises a diode, a photodiode, a single-photon avalanche diode, or an avalanche photodiode.
23. The charged-particle beam apparatus of any one of clauses 21 and 22, wherein the plurality of transistors comprises a plurality of n-type metal oxide semiconductor (NMOS) transistors or a plurality of p-type metal oxide semiconductor (PMOS) transistors.
24. The charged-particle beam apparatus of any one of clauses 21 and 23, wherein the first region comprises a p-type well formed inside the substrate such that a top surface of the p-type well is coplanar with the second surface of the substrate layer.
25. The charged-particle beam apparatus of any one of clauses 21 and 24, wherein the first region comprises a conductive isolation well formed inside the substrate such that a top surface of the p-type well is coplanar with the second surface of the substrate layer.
26. The charged-particle beam apparatus of clause 21, wherein the conductive isolation well forms a p-n junction with a transistor of the plurality of transistors.
27. The charged-particle beam apparatus of any one of clauses 21-26, wherein the second surface is downstream from the first surface with respect to a path of the charged particles.
28. The charged-particle beam apparatus of any one of clauses 21-27, wherein the second surface comprises a substantially topology-less surface.
29. The charged-particle beam apparatus of any one of clauses 21-28, wherein transistors of the plurality of transistors are isolated from each other by junction isolation.
30. The charged-particle beam apparatus of clause 29, wherein transistors of the plurality of transistors are isolated from each other without a dielectric or a shallow trench isolation (STI).
31. A method for fabricating a substrate of a charged-particle detector, the method comprising:
forming a charge sensing element on a first surface of the substrate, the charge sensing element configured to detect charged particles originating from a sample;
forming a plurality of transistors in a first region of a second surface of the substrate, the second surface being opposite the first surface,
wherein a top surface of each transistor of the plurality of transistors is coplanar with a top surface of the first region and with the second surface of the substrate.
32. The method of clause 31, wherein the substrate comprises a silicon layer.
33. The method of any one of clauses 31 and 32, wherein forming the charge sensing element comprises forming a diode, a photodiode, a single-photon avalanche diode, or an avalanche photodiode.
34. The method of any one of clauses 31-33, wherein forming the plurality of transistors comprises forming plurality of n-type metal oxide semiconductor (NMOS) transistors or a plurality of p-type metal oxide semiconductor (PMOS) transistors.
35. The method of any one of clauses 31-34, further comprising forming the first region inside the substrate such that a top surface of the first region is coplanar with the second surface of the substrate.
36. The method of clause 35, wherein forming the first region comprises doping the first region with a p-type dopant to form a p-type well.
37. The method of clause 36, wherein forming the first region comprises forming a conductive isolation well inside the substrate such that a top surface of the p-type well is coplanar with the second surface of the substrate.
38. The method of clause 37, wherein the conductive isolation well forms a p-n junction with a transistor of the plurality of transistors.
39. The method of any one of clauses 31-38, further comprising forming the second surface substantially topology-less.
40. The method of any one of clauses 31-39, further comprising forming a junction isolation to isolate transistors of the plurality of transistors from each other by junction isolation.
41. The method of clause 40, further comprising isolating transistors of the plurality of transistors by forming the isolation without a dielectric or a shallow trench isolation (STI).

The block diagrams in the figures illustrate the architecture, functionality, and operation of possible implementations of systems, methods, and computer hardware or software products according to various example embodiments of the present disclosure. In this regard, each block in a flowchart or block diagram may represent a module, segment, or portion of code, which includes one or more executable instructions for implementing the specified logical functions. It should be understood that in some alternative implementations, functions indicated in a block may occur out of order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes may be made without departing from the scope thereof.

1. A substrate for a charged-particle detector, the substrate comprising:
a charge sensing element formed on a first surface of the substrate and configured to detect charged particles originating from a sample; and
a plurality of transistors formed in a first region of a second surface of the substrate, the second surface being opposite the first surface,
wherein a top surface of each transistor of the plurality of transistors is coplanar with a top surface of the first region and with the second surface of the substrate.

2. The substrate of claim 1, wherein the charge sensing element comprises a diode, a photodiode, a single-photon avalanche diode, or an avalanche photodiode.

3. The substrate of claim 1, wherein the plurality of transistors comprises a plurality of n-type metal oxide semiconductor (NMOS) transistors or a plurality of p-type metal oxide semiconductor (PMOS) transistors.

4. The substrate of claim 1, wherein the first region comprises a p-type well formed inside the substrate such that a top surface of the p-type well is coplanar with the second surface of the substrate.

5. The substrate claim 1, wherein the first region comprises a conductive isolation well formed inside the substrate such that a top surface of a p-type well is coplanar with the second surface of the substrate.

6. The substrate of claim 5, wherein the conductive isolation well forms a p-n junction with a transistor of the plurality of transistors.

7. The substrate of claim 1, wherein the second surface is downstream from the first surface with respect to a path of the charged particles.

8. The substrate of claim 1, wherein the second surface comprises a substantially topology-less surface.

9. The substrate of claim 1, wherein transistors of the plurality of transistors are isolated from each other by junction isolation.

10. The substrate of claim 9, wherein transistors of the plurality of transistors are isolated from each other without a dielectric material or a shallow trench isolation (STI).

11. A charged-particle beam apparatus, comprising:
a charged-particle source configured to emit primary charged particles to be incident on a sample; and
a charged-particle detector configured to detect secondary charged particles generated from the sample upon interaction with the primary charged particles, the charged-particle detector comprising:
a substrate layer comprising a first surface and a second surface opposite the first surface;
a charge sensing element formed on the first surface and configured to detect charged particles originating from a sample; and
a plurality of transistors formed in a first region of the second surface of the substrate layer,
wherein a top surface of each transistor of the plurality of transistors is coplanar with a top surface of the first region and with the second surface of the substrate layer.

12-14. (canceled)

15. A method for fabricating a substrate of a charged-particle detector, the method comprising:
forming a charge sensing element on a first surface of the substrate, the charge sensing element configured to detect charged particles originating from a sample;
forming a plurality of transistors in a first region of a second surface of the substrate, the second surface being opposite the first surface,
wherein a top surface of each transistor of the plurality of transistors is coplanar with a top surface of the first region and with the second surface of the substrate.

16. The charged-particle detector of claim 11, wherein the charge sensing element comprises a diode, a photodiode, a single-photon avalanche diode, or an avalanche photodiode.

17. The charged-particle detector of claim 11, wherein the plurality of transistors comprises a plurality of n-type metal oxide semiconductor (NMOS) transistors or a plurality of p-type metal oxide semiconductor (PMOS) transistors.

18. The charged-particle detector of claim 11, wherein the first region comprises a p-type well formed inside the substrate such that a top surface of the p-type well is coplanar with the second surface of the substrate layer.

19. The charged-particle detector of claim 11, wherein the first region comprises a conductive isolation well formed inside the substrate such that a top surface of a p-type well is coplanar with the second surface of the substrate layer.

20. The charged-particle detector of claim 19, wherein the conductive isolation well forms a p-n junction with a transistor of the plurality of transistors.

21. The charged-particle detector of claim 11, wherein the second surface is downstream from the first surface with respect to a path of the charged particles.

22. The charged-particle detector of claim 11, wherein transistors of the plurality of transistors are isolated from each other by junction isolation.

23. The charged-particle detector of claim 22, wherein transistors of the plurality of transistors are isolated from each other without a dielectric or a shallow trench isolation (STI).
